(19) United States
(12) Patent Application Publication
(10) Pub. No.: US 2022/0246762 A1
(43) Pub. Date: Aug. 4, 2022

(54) METAL GATE AND METHOD FOR MANUFACTURING THE SAME

(71) Applicant: SHANGHAI HUALI INTEGRATED CIRCUIT CORPORATION, Shanghai (CN)

(72) Inventors: Jhencyuan LI, Shanghai (CN); Yingju CHEN, Shanghai (CN); Liyao LIU, Shanghai (CN); Chanyuan HU, Shanghai (CN)

(21) Appl. No.: 17/491,282

(22) Filed: Sep. 30, 2021

(30) Foreign Application Priority Data
Feb. 4, 2021 (CN) 202110153110.1

(51) Int. Cl. H01L 29/78; H01L 29/66

(52) U.S. Cl. CPC H01L 29/7856; H01L 29/66795; H01L 29/66545

(57) ABSTRACT

The present application discloses a metal gate which is formed by replacing a polysilicon pseudo-gate. First a gate trench is created after the polysilicon pseudo-gate is removed. The gate trench is divided into atop trench and a bottom trench. A first sidewall of the polysilicon pseudo-gate is partially remove to the level of the top trench depth and it is then replaced with a second sidewall with a smaller width, such that the width of the top trench is expanded from the width of the first sidewall to the width of the second sidewall, so that the top trench is wider than the bottom trench. The metal gate is then disposed in the gate trench. A method for manufacturing the metal gate is also disclosed. The present application can improve the metal gate filling process window and eliminate the void left by the current metal gate filling process.

### CROSS-REFERENCES TO RELATED APPLICATIONS

This application claims the priority to Chinese patent application No. CN202110153110.1, filed on Feb. 4, 2021, and entitled “METAL GATE AND METHOD FOR MANUFACTURING THE SAME”, the disclosure of which is incorporated herein by reference in entirety.

### TECHNICAL FIELD

The present application relates to the field of semiconductor integrated circuit manufacturing, in particular to a metal gate. The present application further relates to a method for manufacturing the metal gate.

### BACKGROUND

Referring to FIG. 1A, it is a structural view of a normally filled metal gate formed by adopting an existing method for manufacturing the metal gate.

A metal gate 106 is formed on a semiconductor substrate 101, but the metal gate 106 is formed through a filling process, and the metal gate 106 is formed by filling in a gate trench formed after removing a polysilicon pseudo-gate 108 illustrated in FIG. 2A. The structures of the metal gate illustrated in FIGS. 1A and 1B will be described with reference to the structural views after each step in the existing method of manufacturing the metal gate illustrated in FIGS. 2A-2C.

Referring to FIG. 2A, the polysilicon pseudo-gate 108 is first formed on the surface of the semiconductor substrate 101, then sidewalls 102 are formed on two sides of the polysilicon pseudo-gate 108 by using the self-alignment technique on the polysilicon pseudo-gate 108, and a source region and a drain region are formed through self-aligned source and drain implantation by using the sidewalls 102 as self-alignment masks. Source and drain implantation is followed by annealing activation.

After forming the sidewalls 102 and forming the source region and drain region, a contact etch stop layer (CESL) 103 and an interlayer film 104 are disposed. The contact etch stop layer 103 usually contains silicon nitride, and the interlayer film 104 usually includes silicon oxide.

After forming the contact etch stop layer and the interlayer film, a chemical-mechanical polishing process is performed to expose the surface of the polysilicon pseudo-gate 108 and to make sure that the surface of the interlayer film 104 is in flush with the surface of the polysilicon pseudo-gate 108.

Referring to FIG. 2B, the polysilicon pseudo-gate 108 is fully removed by adopting an etching process to form a gate trench 109.

Referring to FIG. 2C, then a gate dielectric layer and a work function layer are sequentially disposed in the gate trench. In FIG. 2C, a layer 105 is the superposition layer of the gate dielectric layer and the work function layer.

Referring to FIG. 1A, the metal gate 106 fills in the gate trench 109 on top of the gate dielectric layer and the work function layer. In most of the times, the metal gate 106 can seamlessly fill the trench, shown as the structure illustrated in FIG. 1A.

However, with the continuous reduction of the process dimensions, such as in the process nodes down to 32 nm, 28 nm and even below 22 nm, the critical dimension (CD), in this case, the width of the gate trench 109 has become ever smaller. In addition, the gate trench 109 is further reduced after the gate dielectric layer and work function layer are disposed into the trench ahead of the metal gate 106. As the result, a void 107 as illustrated in FIG. 1B is likely formed. This type of voids will affect the performance of the device and even fail the device.

### BRIEF SUMMARY

The present application provides a metal gate made with a void-free filling process window. The present application further provides a method for manufacturing the metal gate.

This metal gate is formed in the region to replace a polysilicon pseudo-gate.

The polysilicon pseudo-gate is first formed on a semiconductor substrate, a first sidewall is formed through self-alignment on a side surface of the polysilicon pseudo-gate, and an interlayer film is disposed in a region within the polysilicon pseudo-gate, herein the surface of the interlayer film is in flush with the surface of the polysilicon pseudo-gate.

A gate trench formed after the polysilicon pseudo-gate is removed includes a top trench and a bottom trench.

The first sidewall within the range of the top trench depth is removed, a side surface of the interlayer film is exposed from the top trench, and a second sidewall is formed through self-alignment on the side surface of the interlayer film in the top trench; the width of the second sidewall is less than the width of the first sidewall, the width of the top trench is expanded from the spacing of the first sidewall to the spacing of the second sidewall, and the width of the top trench is more than the width of the bottom trench, such that the gate trench has a structure which is wider at the top.

The top width of the gate trench is wider than the bottom width, thus the metal gate filling process window is increased, resulting a seamless the metal gate filling structure.

A gate dielectric layer and a work function layer are formed between the metal gate and an inner side surface of the gate trench.

As an example, the semiconductor substrate includes a silicon substrate.

As an example, the material of the first sidewall is silicon nitride, the material of the second sidewall is silicon nitride, and the material of the interlayer film is silicon oxide.

As an example, a contact etch stop layer is formed on a side surface of the first sidewall and the surface of the semiconductor substrate outside the first sidewall; the material of the contact etch stop layer is the same as the material of the first sidewall.

The contact etch stop layer within the depth range of the top trench is also removed, and the width of the second sidewall is less than the width of the contact etch stop layer.

As an example, the gate dielectric layer includes a high-dielectric-constant layer, and a high-dielectric-constant metal gate is formed by superposing the gate dielectric layer, the work function layer and the metal gate.

As an example, the high-dielectric-constant metal gate is formed on a fin body and is used as a gate structure of a FinFET transistor; the fin body is formed by performing patterning etching to the semiconductor substrate, and the fin body protrudes out of the surface of the etched semiconductor substrate.

As an example, an embedded epitaxial layer is formed in the fin body on the two sides of the high-dielectric-constant metal gate, a source region and a drain region are formed in the embedded epitaxial layer on the two sides of the high-dielectric-constant metal gate, a channel region is formed between the source region and the drain region and is covered by the high-dielectric-constant metal gate, and the embedded epitaxial layer provides stress that increases carrier mobility for the channel region.

As an example, the gate trench further includes a transition trench, and a side surface of the transition trench is inclined and located between the top trench and the bottom trench, such that the width of the gate trench is gradually reduced from top to bottom.

A method for manufacturing the metal gate includes the following steps:

step 1: providing a semiconductor substrate, forming a polysilicon pseudo-gate on the semiconductor substrate, forming a first sidewall through self-alignment on a side surface of the polysilicon pseudo-gate, disposing an interlayer film in a region within the polysilicon pseudo-gate, herein the surface of the interlayer film is in flush with the surface of the polysilicon pseudo-gate;

step 2: performing first etching, wherein the first etching removes part of the thickness of the polysilicon pseudo-gate and forms a top trench;

step 3: performing second etching, wherein the second etching removes the first sidewall within the range of the top trench depth and exposes a side surface of the interlayer film in the top trench;

step 4: forming a second sidewall through self-alignment on the side surface of the interlayer film in the top trench, wherein the width of the second sidewall is less than the width of the first sidewall, the width of the top trench is expanded from the spacing of the first sidewall to the spacing of the second sidewall;

step 5: performing the third etching, wherein the third etching removes the remaining polysilicon pseudo-gate and forms a bottom trench, wherein the width of the bottom trench is the spacing of the first sidewall, wherein the bottom trench and the top trench are superposed to form a gate trench, the gate trench has a structure which is wider at the top than the bottom;

step 6: forming a gate dielectric layer on an inner side surface of the gate trench, and forming a work function layer on the surface of the gate dielectric layer; then, filling the metal gate in the gate trench, wherein the structure of the gate trench has a wider top than the bottom, thus the metal gate filling process window has increased, as the result, the metal gate has a seamless filling structure.

As an example, the semiconductor substrate includes a silicon substrate.

As an example, the material of the first sidewall is silicon nitride, the material of the second sidewall is silicon nitride, and the material of the interlayer film is silicon oxide.

As an example, a contact etch stop layer is formed on a side surface of the first sidewall and the surface of the semiconductor substrate outside the first sidewall; wherein the material of the contact etch stop layer is the same as the material of the first sidewall; and

the second etching removes the contact etch stop layer within the range of the top trench depth; wherein the width of the second sidewall is less than the width of the contact etch stop layer.

As an example, the gate dielectric layer includes a high-dielectric-constant layer, and a high-dielectric-constant metal gate is formed by superposing the gate dielectric layer, the work function layer and the metal gate.

As an example, the high-dielectric-constant metal gate is formed on a fin body and is used as a gate structure of a FinFET transistor; the fin body is formed by performing patterning etching to the semiconductor substrate, and the fin body protrudes out of the surface of the etched semiconductor substrate.

As an example, an embedded epitaxial layer is formed in the fin body on the two sides of the high-dielectric-constant metal gate, a source region and a drain region are formed in the embedded epitaxial layer on the two sides of the high-dielectric-constant metal gate, a channel region is formed between the source region and the drain region and is covered by the high-dielectric-constant metal gate, and the embedded epitaxial layer provides a stress that increases carrier mobility for the channel region.

As an example, in step 4, the second sidewall is formed by adopting a deposition and comprehensive etching process.

As an example, the first etching is dry etching, the second etching is dry etching, and the third etching is dry etching or wet etching.

As an example, after the comprehensive etching process of the second sidewall is completed and before the third etching, the method further includes performing a fourth etching to form a transition trench, and a side surface of the transition trench is inclined and located between the top trench and the bottom trench, such that the width of the gate trench is gradually reduced from top to bottom.

The gate trench filled with a metal gate in the present application is not formed by directly etching the polysilicon pseudo-gate, but by combining the etching of the polysilicon pseudo-gate, the etching of the first sidewall on the side surface of the polysilicon pseudo-layer and the forming process of the second sidewall to form the gate trench. With the characteristic that the width of the second sidewall is less than the width of the first sidewall, the top width of the gate trench is increased, so the gate trench has a wider top than the bottom, and is conducive to the filling of the metal gate. Therefore, the present application can increase the metal gate filling process window and enable a seamless metal gate filling structure, thus improving the manufacturing yield of the metal gate.

The present application is especially suitable for the filling process of the metal gate at the process nodes of 32 nm, 28 nm, 22 nm and beyond, such that the metal gate can still be free of void at a small dimension.

The gate trench provided by the present application can be implemented by proper controlling of the etching of the polysilicon pseudo-gate, the etching of the first sidewall and the forming process of the second sidewall, including deposition and etching, these processes can be realized through self-alignment without adopting an additional lithographic process for definition. Therefore, the present application further has the characteristic of a low process cost.

### BRIEF DESCRIPTION OF THE DRAWINGS

The embodiments of the present application will be further described below in detail with reference to the drawings.

FIG. 1A is a structural view of a desired metal gate formed by an existing method for manufacturing the metal gate.

FIG. 1B is a structural view of a defective metal gate formed by an existing method for manufacturing the metal gate.

FIG. 2A to FIG. 2C are structural schematic views in each step of an existing method for manufacturing the metal gate.

FIG. 3 is a structural view of a metal gate fabricated with a method according to one embodiment of the present application.

FIGS. 4A to 4H are structural schematic views in each step of a method for manufacturing the metal gate fabricated according to one embodiment of the present application.

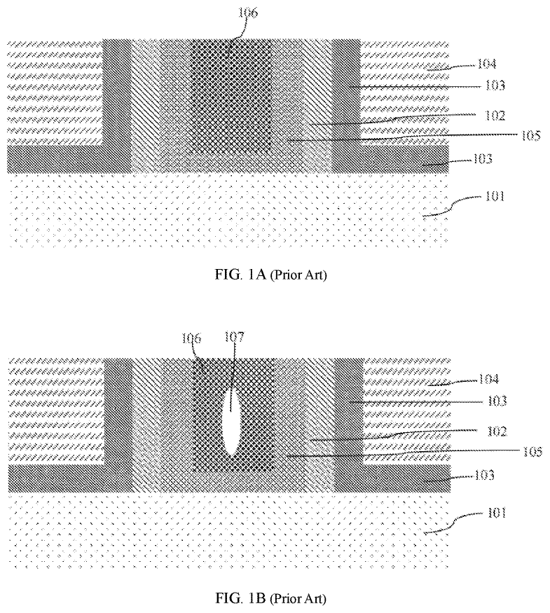

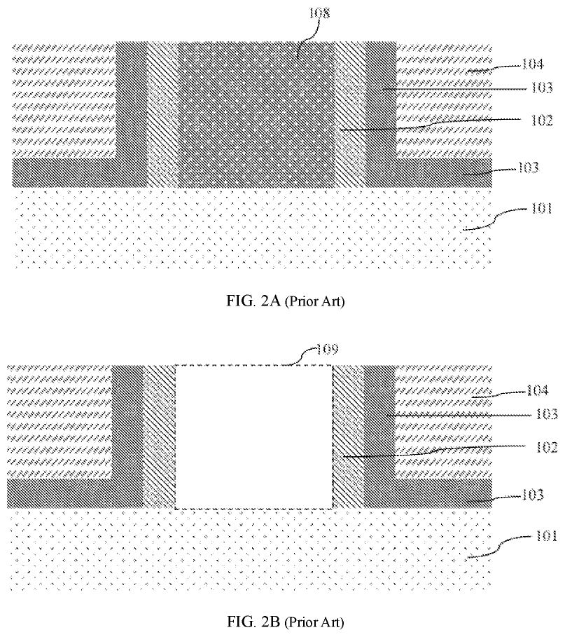

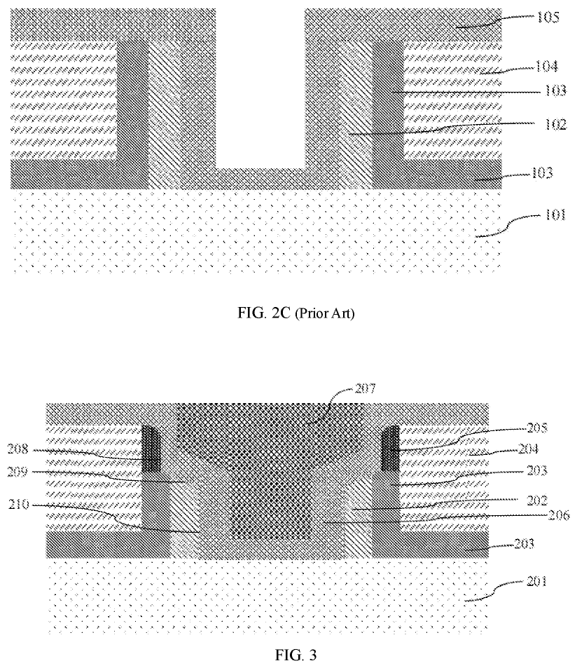

### DETAILED DESCRIPTION OF THE APPLICATOIN

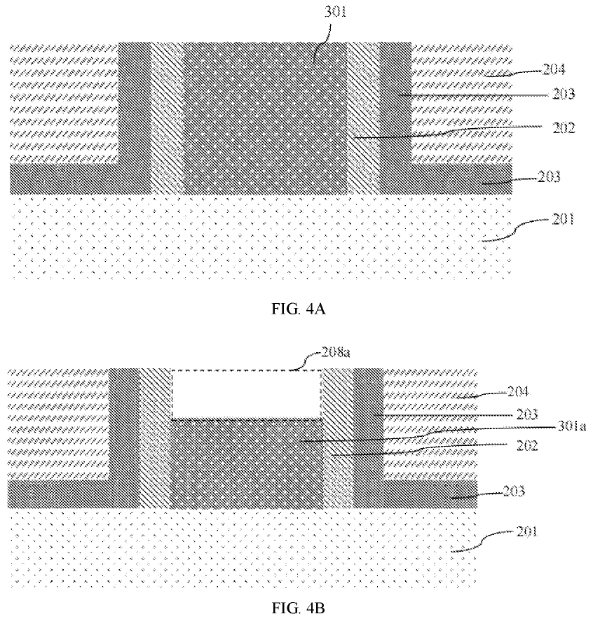

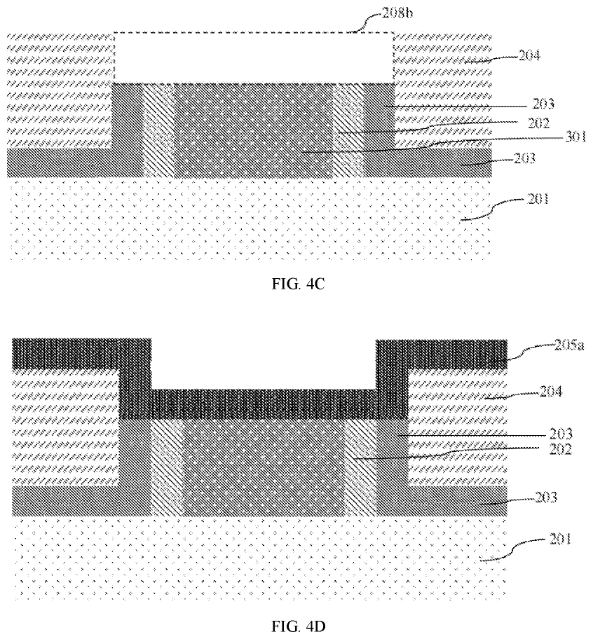

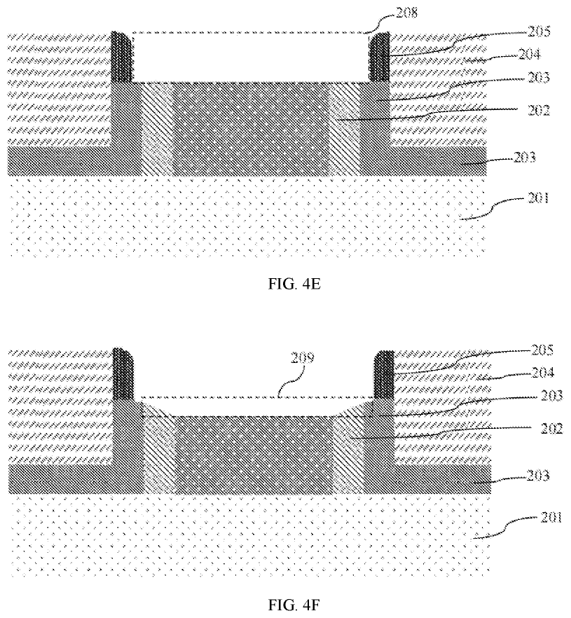

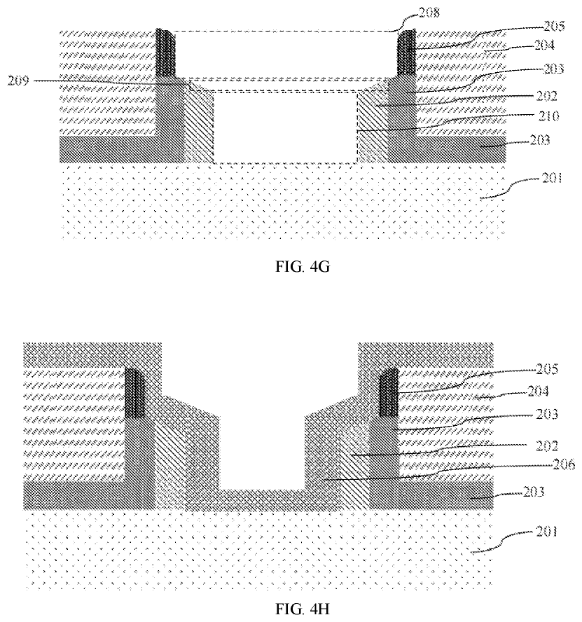

Referring to FIG. 3 and FIG. 4, it is a structural view of a metal gate 207 according to one embodiment of the present application. A region of the metal gate 207 is formed is defined by the removed polysilicon pseudo-gate 301 according to the embodiment of the present application.

In FIG. 4A, the polysilicon pseudo-gate 301 is formed on a semiconductor substrate 201, a first sidewall 202 is formed through self-alignment on a side surface of the polysilicon pseudo-gate 301, an interlayer film 204 is filled in a region within the polysilicon pseudo-gate 301 and is in flush with the surface of the polysilicon pseudo-gate 301

In the embodiment of the present application, the semiconductor substrate 201 includes a silicon substrate.

The material of the first sidewall 202 is silicon nitride, and the material of the interlayer film 204 is silicon oxide.

The contact etch stop layer 203 is formed on a side surface of the first sidewall 202 and the surface of the semiconductor substrate 201 outside the first sidewall 202; the material of the contact etch stop layer 203 is the same as the material of the first sidewall 202.

Shown in FIG. 4G, a gate trench is formed as the polysilicon pseudo-gate 301 is removed, this gate trench includes a top trench 208 and a bottom trench 210.

Shown in FIG. 4C, the first sidewall 202 and the contact etch stop layer 203 are both partially removed down to the level of the top trench 208 depth. After this etch, a side surface of the interlayer film 204 is exposed in the top trench 208. As shown in FIG. 4E, a second sidewall 205 is formed through self-alignment on the exposed side surface of the interlayer film 204 in the top trench 208, wherein the width of the second sidewall 205 is less than the width of the first sidewall 202, the width of the top trench 208 is therefore expanded from the extra room from the width of the first sidewall 202 minus the width of the second sidewall 205. So as shown in FIG. 4G, the width of the top trench 208 is larger than the width of the bottom trench 210, such that the gate trench has a structure having a wider top.

In the embodiment of the present application, when the contact etch stop layer 203 is partially removed down to the level of the top trench 208's depth, and the second sidewall 205 has a width narrower than the width of the original contact etch stop layer 203.

The material of the second sidewall 205 is silicon nitride.

The gate trench further includes a transition trench 209 as shown in FIG. 4F, and side surfaces of the transition trench 209 are inclined and located between the top trench 208 and the bottom trench 210, such that the width of the gate trench is gradually reduced from the width of the top trench 208 to the width of the bottom trench 210.

The metal gate 207 is disposed in the gate trench, and the structure of the gate trench which is wider at the top increases the filling process window for the metal gate 207 and enables a seamless filling structure for the metal gate.

Agate dielectric layer and a work function layer are then formed between the metal gate 207 and an inner side surface of the gate trench. In FIG. 3, a stack of layers 206 is a superposition of the gate dielectric layer and the work function layer.

The gate dielectric layer includes a high-dielectric-constant layer, and a high-dielectric-constant metal gate 207 is formed by superposing the gate dielectric layer, the work function layer and the metal gate 207.

The high-dielectric-constant layer typically comprises hafnium oxide; an interface layer is formed between the high-dielectric-constant layer and the semiconductor substrate 201, and the interface layer is usually an oxide layer (not shown in FIG. 3).

A bottom barrier layer (not shown) is disposed between the high-dielectric-constant layer and the work function layer, and a top barrier layer (not shown) is disposed between the work function layer and the metal gate 207.

The high-dielectric-constant metal gate 207 is formed on a fin body and served as a gate structure of a FinFET transistor. The fin body is formed by performing patterning etching to the semiconductor substrate 201, and the fin body protrudes out of the surface of the etched semiconductor substrate 201. The cross sectional structure illustrated in FIG. 3 is a structure viewed along the length direction of the fin body, so the fin body and the semiconductor substrate 201 at the bottom of the fin body are in an integrated structure.

An embedded epitaxial layer (not shown) is formed in the fin body on the two sides of the high-dielectric-constant metal gate 207, a source region and a drain region are formed in the embedded epitaxial layer on the two sides of the high-dielectric-constant metal gate 207, a channel region is formed between the source region and the drain region and is covered by the high-dielectric-constant metal gate 207, and the embedded epitaxial layer provides stress that increases carrier mobility for the channel region.

When the FinFET is an N-type device, the embedded epitaxial layer includes SiP, the work function layer is an N-type work function layer, and the material of the N-type work function layer includes TiAl.

When the FinFET is a P-type device, the embedded epitaxial layer includes SiGe, the work function layer is a P-type work function layer, and the material of the P-type work function layer includes TiN.

According to the embodiment of the present application, the gate trench filled with the metal gate 207 is not formed by directly etching the polysilicon pseudo-gate 301, but instead by combining the etching of the polysilicon pseudo-gate 301, the etching of the first sidewall 202 on the side surface of the polysilicon pseudo-layer and the forming process of the second sidewall 205 to form the gate trench. By creating the process such that the width of the second sidewall 205 is less than the width of the first sidewall 202, then the top width of the gate trench can be increased, so as to form the gate trench which is wider at the top, this is conducive to the filling of the metal gate 207. Therefore, the present application can improve the filling process window of the metal gate 207 and enable a seamless filling structure for the metal gate 207, thus improving the manufacturing yield of the metal gate 207.

The present application is especially suitable for the filling process of the metal gate 207 at the process node of 32 nm, 28 nm, 22 nm and beyond, even at smaller metal gate critical dimensions.

The gate trench provided by the embodiment of the present application can be implemented by controlling the etching of the polysilicon pseudo-gate 301, the etching of the first sidewall 202 and the forming process of the second sidewall 205, including deposition and etching, which can be realized through self-alignment without adopting an additional lithographic process for definition. Therefore, the embodiment of the present application further has the characteristic of low process cost.

FIG. 4A to FIG. 4H are structural schematic views at each step of the method for manufacturing the metal gate according to one embodiment of the present application. The method for manufacturing the metal gate according to one embodiment of the present application includes the following steps:

In step 1, referring to FIG. 4A, a semiconductor substrate 201 is provided, a polysilicon pseudo-gate 301 is formed on the semiconductor substrate 201, a first sidewall 202 is formed through self-alignment on a side surface of the polysilicon pseudo-gate 301, an interlayer film 204 is disposed on the etch stop layer 203 in a region near the polysilicon pseudo-gate 301 and its top surface is in flush with the surface of the polysilicon pseudo-gate 301.

In the method according to the embodiment of the present application, the semiconductor substrate 201 includes a silicon substrate.

The material of the first sidewall 202 is silicon nitride, and the material of the interlayer film 204 is silicon oxide.

A contact etch stop layer 203 is formed on a side surface of the first sidewall 202 and the surface of the semiconductor substrate 201 outside the first sidewall 202; the material of the contact etch stop layer 203 is the same as the material of the first sidewall 202.

The polysilicon pseudo-gate 301 is formed on the fin body; the fin body is formed by performing patterning etching to the semiconductor substrate 201, and the fin body protrudes out of the surface of the etched semiconductor substrate 201. The cross sectional view of the structure in FIG. 4A is cut along the length direction of the fin body, so the fin body and the semiconductor substrate 201 are in an integrated structure.

An embedded epitaxial layer is formed in the fin body on the two sides of the polysilicon pseudo-gate 301, a source region and a drain region are formed in the embedded epitaxial layer on the two sides of the high-dielectric-constant metal gate 207, a channel region is formed between the source region and the drain region and is covered by the high-dielectric-constant metal gate 207, and the embedded epitaxial layer provides stress that increases carrier mobility for the channel region.

When the FinFET is an N-type device, the embedded epitaxial layer includes SiP.

When the FinFET is a P-type device, the embedded epitaxial layer includes SiGe.

In step 2, referring to FIG. 4B, first etching is performed, and the first etching removes part of the thickness of the polysilicon pseudo-gate 301 and forms a top trench 208a. In FIG. 4B, the top trench formed after the first etching is referenced as 208a.

The first etching is dry etching.

In step 3, referring to FIG. 4C, second etching is performed, and the second etching partially removes the first sidewall 202 and the contact etch stop layer 203 down to the level of the top trench depth 208a and exposes a side surface of the interlayer film 204 in the top trench 208b. In FIG. 4C, the top trench 208 formed after the second etching is referenced as 208b.

In the method according to the embodiment of the present application, in removing the contact etch stop layer 203 partially to create the top trench 208, the second etching is applied.

The second etching is dry etching.

In step 4, referring to FIG. 4E, a second sidewall 205 is formed through self-alignment on the side surface of the interlayer film 204 in the top trench 208, the width of the second sidewall 205 is less than the width of the first sidewall 202, the width of the top trench 208 is expanded from the spacing of the first sidewall 202 to the spacing of the second sidewall 205. In FIG. 4E, the top trench after the formation of the second sidewall 205 is referenced as 208; compared with the width of the top trench corresponding to the reference 208a in FIG. 4B which is the spacing of the first sidewall 202, the width of the top trench 208 in FIG. 4E is the spacing of the second sidewall 205, and so the width of the top trench 208 is expanded, which is conducive to the filling of the thick metal gate 207, such that after the metal gate 207 is filled, the top side surface of the metal gate 207 still has the second sidewall 205.

In the method according to the embodiment of the present application, the material of the second sidewall 205 is silicon nitride.

The width of the second sidewall 205 is also less than the width of the contact etch stop layer 203.

In step 4, the second sidewall 205 is formed by adopting a deposition and comprehensive etching process. Referring to FIG. 4D, a material layer 205a of the second sidewall 205 is formed by adopting a deposition process; then, referring to FIG. 4E, the material layer 205a is comprehensively etched to form the second sidewall 205.

Preferably, referring to FIG. 4F, after the comprehensive etching process of the second sidewall 205 is completed and before the third etching, the method further includes performing fourth etching to form a transition trench 209, and a side surface of the transition trench 209 is inclined and located between the top trench 208 and the bottom trench 210, such that the width of the gate trench is gradually reduced from the width of the top trench 208 to the width of the bottom trench 210.

In step 5, referring to FIG. 4G, third etching is performed, the third etching removes the remaining polysilicon pseudo-gate 301 and forms a bottom trench 210, the width of the bottom trench 210 is the spacing of the first sidewall 202, the bottom trench 210 and the top trench 208 are combined to form a gate trench, and the gate trench has a structure which is wider at the top.

The third etching adopts dry etching or wet etching.

In step 6, referring to FIG. 4H, a gate dielectric layer is formed on an inner side surface of the gate trench, and a work function layer is formed on a surface of the gate dielectric layer; a superposition layer of the gate dielectric layer and the work function layer is represented by a layer 206.

Then, referring to FIG. 3, a metal gate 207 is filled in the gate trench, and the structure of the gate trench which is wide at the top and narrow at the bottom increases the filling process window of the metal gate 207 and makes the metal gate 207 have a seamless filling structure.

In the method according to the embodiment of the present application, the gate dielectric layer includes a high-dielectric-constant layer, and a high-dielectric-constant metal gate 207 is formed by superposing the gate dielectric layer, the work function layer and the metal gate 207.

The high-dielectric-constant metal gate 207 is formed on a fin body and is used as a gate structure of a FinFET transistor.

The high-dielectric-constant layer is usually hafnium oxide; an interface layer is formed between the high-dielectric-constant layer and the semiconductor substrate 201, and the interface layer is usually an oxide layer.

A bottom barrier layer is provided between the high-dielectric-constant layer and the work function layer, and a top barrier layer is provided between the work function layer and the metal gate 207.

When the FinFET is an N-type device, the work function layer is an N-type work function layer, and the material of the N-type work function layer includes TiAl.

When the FinFET is a P-type device, the work function layer is a P-type work function layer, and the material of the P-type work function layer includes TiN.

The present application has been described above in detail through specific embodiments, which, however, do not constitute limitations to the present application. Without departing from the principle of the present application, those skilled in the art may make various modifications and improvements, which should also be regarded as the scope of protection of the present application.

1. A metal gate, wherein the metal gate replaces a polysilicon pseudo-gate, the metal gate comprising:
a semiconductor substrate, wherein the polysilicon pseudo-gate is formed on the semiconductor substrate, a first sidewall is formed through self-alignment on a side surface of the polysilicon pseudo-gate, and an interlayer film is disposed in a region near the polysilicon pseudo-gate, wherein a top surface of the interlayer film is in flush with a top surface of the polysilicon pseudo-gate;
wherein the polysilicon pseudo-gate is removed to create a gate trench to form the metal gate;
wherein the gate trench comprises a top trench and a bottom trench;
wherein the first sidewall is partially removed down to a level of the top trench depth, such that a side surface of the interlayer film is exposed in the top trench;
wherein a second sidewall is formed through self-alignment on the side surface of the interlayer film in the top trench; wherein a width of the second sidewall is less than a width of the first sidewall, expanding a width of the top trench; wherein the width of the top trench is wider than a width of the bottom trench for an easier filling of the metal gate; and
wherein a gate dielectric layer and a work function layer are formed between the metal gate and an inner side surface of the gate trench.

2. The metal gate according to claim 1, wherein the semiconductor substrate comprises a silicon substrate.

3. The metal gate according to claim 1, wherein a material of the first sidewall comprises silicon nitride, a material of the second sidewall comprises silicon nitride, and a material of the interlayer film comprise silicon oxide.

4. The metal gate according to claim 3, wherein a contact etch stop layer is formed on a side surface of the first sidewall and a surface of the semiconductor substrate outside the first sidewall; wherein a material of the contact etch stop layer comprise a same material as the first sidewall; and
wherein the contact etch stop layer is partially removed down to the level of the top trench depth, wherein the width of the second sidewall is narrower than a width of the contact etch stop layer.

5. The metal gate according to claim 1, wherein the gate dielectric layer comprises a high-dielectric-constant layer, and wherein a high-dielectric-constant metal gate is formed by superposing the gate dielectric layer, the work function layer and the metal gate.

6. The metal gate according to claim 5, wherein the high-dielectric-constant metal gate is formed on a fin body and is used as a gate structure of a FinFET transistor; wherein the fin body is formed by performing patterning etching to the semiconductor substrate, and wherein the fin body protrudes out of a surface of the semiconductor substrate.

7. The metal gate according to claim 6, wherein an embedded epitaxial layer is formed in the fin body on two sides of the high-dielectric-constant metal gate, wherein a source region and a drain region are formed in the embedded epitaxial layer on the two sides of the high-dielectric-constant metal gate, wherein a channel region is formed between the source region and the drain region and is covered by the high-dielectric-constant metal gate, and wherein the embedded epitaxial layer provides a stress that increases carrier mobility for the channel region.

8. The metal gate according to claim 1, wherein the gate trench further comprises a transition trench, and a side surface of the transition trench is inclined and located between the top trench and the bottom trench, such that the width of the gate trench is gradually reduced from the width of the top trench to the width of the bottom trench.

9. A method for manufacturing a metal gate, comprising steps of:
step 1: providing a semiconductor substrate, wherein a polysilicon pseudo-gate bis formed on the semiconductor substrate, wherein a first sidewall is formed through self-alignment on a side surface of the polysilicon pseudo-gate, wherein an interlayer film being is disposed in a region near the polysilicon pseudo-gate, and wherein a top surface of the interlayer film is in flush with the surface of the polysilicon pseudo-gate;
step 2: performing a first etching, wherein the first etching removes a part of the polysilicon pseudo-gate and forms a top trench;
step 3: performing a second etching, wherein the second etching removes the first sidewall partially down to a level of the top trench depth and exposes a side surface of the interlayer film in the top trench;
step 4: forming a second sidewall through self-alignment on the side surface of the interlayer film in the top trench, wherein a width of the second sidewall is narrower than a width of the first sidewall, expanding a width of the top trench;
step 5: performing a third etching, wherein the third etching removes a remaining part of the polysilicon pseudo-gate and forms a bottom trench, wherein a width of the bottom trench has an original first sidewall so comprises a width not expanded, wherein the bottom trench and the top trench are combined to form a gate trench, wherein the gate trench has a wider top than a bottom; and
step 6: forming a gate dielectric layer on an inner side surface of the gate trench, and forming a work function layer on a surface of the gate dielectric layer; and filling a metal gate in the gate trench with the wider top.

10. The method for manufacturing the metal gate according to claim 9, wherein the semiconductor substrate comprises a silicon substrate.

11. The method for manufacturing the metal gate according to claim 9, wherein a material of the first sidewall is silicon nitride, a material of the second sidewall is silicon nitride, and a material of the interlayer film is silicon oxide.

12. The method for manufacturing the metal gate according to claim 11, wherein a contact etch stop layer is formed on a side surface of the first sidewall and the surface of the semiconductor substrate outside the first sidewall; wherein a material of the contact etch stop layer is a same as the material of the first sidewall;
wherein the second etching removes the contact etch stop layer down to the top trench depth; and
wherein a width of the second sidewall is narrower than a width of the contact etch stop layer.

13. The method for manufacturing the metal gate according to claim 9, wherein the gate dielectric layer comprises a high-dielectric-constant layer, and wherein a high-dielectric-constant metal gate is formed by superposing the gate dielectric layer, the work function layer and the metal gate.

14. The method for manufacturing the metal gate according to claim 13, wherein the high-dielectric-constant metal gate is formed on a fin body and is used as a gate structure of a FinFET transistor; wherein the fin body is formed by performing patterning etching to the semiconductor substrate; and wherein the fin body protrudes out of the surface of the etched semiconductor substrate.

15. The method for manufacturing the metal gate according to claim 14, wherein an embedded epitaxial layer is formed in the fin body on two sides of the high-dielectric-constant metal gate, wherein a source region and a drain region are formed in the embedded epitaxial layer on the two sides of the high-dielectric-constant metal gate, wherein a channel region is formed between the source region and the drain region and is located under the high-dielectric-constant metal gate, and wherein the embedded epitaxial layer provides a stress that increases carrier mobility for the channel region.

16. The method for manufacturing the metal gate according to claim 9, wherein in step 4, the second sidewall is formed by adopting a deposition and comprehensive etching process.

17. The method for manufacturing the metal gate according to claim 9, wherein the first etching is dry etching, the second etching is dry etching, and the third etching is dry etching or wet etching.

18. The method for manufacturing the metal gate according to claim 16, wherein after the comprehensive etching process on the second sidewall is completed and before the third etching, the method further comprises performing fourth etching to form a transition trench, wherein a side surface of the transition trench is inclined and located between the top trench and the bottom trench, such that a width of the gate trench is gradually reduced from the width of the top trench to the width of the bottom trench.
